(19) United States
(12) Patent Application Publication
(10) Pub. No.: US 2011/0036622 A1
(43) Pub. Date: Feb. 17, 2011

(54) LAMINATED CERAMIC ELECTRONIC COMPONENT AND METHOD FOR MANUFACTURING THE SAME

(75) Inventors: Osamu CHIKAGAWA, Echizen-shi (JP); Tetsuya IKEDA, Kyoto-shi (JP)

Correspondence Address: MURATA MANUFACTURING COMPANY, LTD.;C/O KEATING & BENNETT, LLP, 1800 Alexander Bell Drive, SUITE 200, Reston, VA, 20191, US

(73) Assignee: MURATA MANUFACTURING CO., LTD., Nagaokakyo-shi (JP)

(21) Appl. No.: 12/850,707

(22) Filed: Aug. 5, 2010

(30) Foreign Application Priority Data
Aug. 12, 2009 (JP) 2009-187262

(51) Int. Cl. H05K 1/09; B29C 65/02

(52) U.S. Cl. 174/257; 156/89.17

(57) ABSTRACT

In a method for manufacturing a laminated ceramic electronic component, in order to form a green ceramic laminate to be fired, first ceramic green layers which include first conductor patterns including Ag as a main component and which include a first ceramic material including a first glass component are disposed in surface layer portions. Second ceramic green layers which include second conductor patterns including Ag as a main component, which include a second ceramic material containing a second glass component, and which include a composition in which Ag diffuses than more easily in the first ceramic green layer during firing are disposed in inner layer portions. The green ceramic laminate is fired to produce a multilayer ceramic substrate.

### BACKGROUND OF THE INVENTION

1. Field of the Invention

The present invention relates to a laminated ceramic electronic component and a method for manufacturing the same. In particular, the present invention relates to an improvement for suppressing Ag migration on a surface of a laminated ceramic electronic component.

2. Description of the Related Art

An example of a multilayer ceramic substrate includes a plurality of laminated ceramic layers and conductor patterns provided on surfaces and inside the substrate. Examples of the conductor patterns include an in-plane conductor extending in a planar direction of a ceramic layer and an interlayer connecting conductor (typically a via hole conductor) extending to pass through a ceramic layer in the thickness direction.

In general, surface-mount type electronic components, such as a semiconductor device or a chip laminated capacitor, for example, are mounted and wired together on such a multilayer ceramic substrate. The multilayer ceramic substrate may include built-in passive elements, such as a capacitor or an inductor, for example. These passive elements are defined by the in-plane conductor or the interlayer connecting conductor and, if required, are connected to the surface mount-type electronic components.

As a conductive material for the conductor patterns provided on the multilayer ceramic substrate, a conductor including Ag as a main component is widely used. This is because the Ag-based conductor has low electric resistance, and it is not necessary to use a neutral or reduced atmosphere in a firing step for producing the multilayer ceramic substrate, and instead, an oxidizing atmosphere, such as air, can be used. In addition, as a ceramic material defining ceramic layers provided in the multilayer ceramic substrate, a low-temperature sintering ceramic material which can be sintered at a temperature lower than the melting point of the Ag-based conductor is used. This is also considered to contribute to the wide use of the Ag-based conductor.

Sintering of the low-temperature sintering ceramic material is generally achieved in a firing step in which a glass component forms a liquid phase to cause rearrangement of a ceramic powder as a filler and the liquid phase of the glass component flows to fill gaps between ceramic particles, thereby increasing the density of the material. In this case, the glass component is previously added as a glass powder to the low-temperature sintering ceramic material or is produced from the low-temperature sintering ceramic material in the firing step.

With respect to reliability of the conductor patterns made of an Ag-based conductor in the multilayer ceramic substrate, the conductor pattern disposed on a surface of the multilayer ceramic substrate generally has a reliability that is less than the conductor pattern disposed on an inner layer of the multilayer ceramic substrate because atmospheric moisture adsorbs on a surface of the multilayer ceramic substrate, thereby easily causing migration. Therefore, among the conductor patterns made of an Ag-based conductor, the conductor pattern disposed on a surface may be surface-treated by, for example, Ni/Au plating to prevent direct contact with moisture.

However, Ag has the property of easily diffusing into glass included in a low-temperature sintering ceramic material which defines a ceramic layer, for example, during the firing step. Therefore, in some cases, Ag diffuses on a surface of the multilayer ceramic substrate after firing. In this case, Ag diffusing on a surface of the multilayer ceramic substrate is primarily exposed to atmospheric moisture because the plating film used for the surface treatment is formed only on the conductor pattern.

Therefore, when Ag diffuses on a surface of the multilayer ceramic substrate, a migration path of Ag is formed between conductor patterns on the surface. As a result, it may be difficult to maintain the reliability of the multilayer ceramic substrate.

In view of this problem caused by using an Ag-based conductor in a conductor pattern, Japanese Examined Patent Application Publication No 3-78798 discloses that a Cu-based conductor is used only for a conductor pattern on a surface in order to suppress the occurrence of migration due to Ag diffusion on a surface.

According to Japanese Examined Patent Application Publication No 3-78798, a conductor pattern made of a Cu-based conductor is provided, and thus, firing cannot be performed in an oxidizing atmosphere. Therefore, Japanese Examined Patent Application Publication No 3-78798 describes that a firing step for forming a multilayer ceramic substrate is performed by a two-step firing process including firing in a neutral or oxidizing atmosphere before a conductor pattern is formed on a surface and subsequently firing in a neutral or reducing atmosphere after a conductor pattern made of a Cu-based conductor is formed on a surface.

However, this method has a problem of requiring a lot of time for firing and a complicated process. On the other hand, firing may be performed at one time after a conductor pattern made of a Cu-based conductor is formed. However, in this case, the firing atmosphere is limited, which causes difficulties in adjusting the atmosphere.

### SUMMARY OF THE INVENTION

Preferred embodiments of the present invention provide a laminated ceramic electronic component, such as a multilayer ceramic substrate, which overcomes the above-described problems and a method for manufacturing the same.

According to a preferred embodiment of the present invention, a method for manufacturing a laminated ceramic electronic component includes the steps of forming a green ceramic laminate and firing the green ceramic laminate, the green ceramic laminate including a first ceramic green layer which includes a first conductor pattern including Ag as a main component and which includes a first ceramic material including a first glass component, and a second ceramic green layer which includes a second conductor pattern including Ag as a main component, which includes a second ceramic material including a second glass component, and which has a composition in which Ag more easily diffuses than in the first ceramic green layer during firing. The first ceramic green layer is disposed along each of both main surfaces while at least a portion of the first conductor pattern is exposed on a surface.

According to another preferred embodiment of the present invention, the first glass component preferably has a higher softening point than the second glass component such that, in the second ceramic green layer, Ag more easily diffuses than in the first ceramic green layer during firing. For example, the first glass component preferably has a lower content of alkali metal oxide or a lower content of boron oxide than that of the second glass component, so that the first and second glass components have different softening points as described above.

According to another preferred embodiment of the present invention, the first glass component and the second glass component preferably include common constituent elements.

According to another preferred embodiment of the present invention, a laminated ceramic electronic component includes a first ceramic layer which includes a first conductor pattern including Ag as a main component and which includes a first glass component, and a second ceramic layer which includes a second conductor pattern including Ag as a main component and which includes a second glass component. The first ceramic green layer is arranged to define a surface layer portion while at least a portion of the first conductor pattern is exposed on a surface. The second ceramic layer is arranged to define an inner layer portion. The amount of Ag diffusion near the first conductor pattern of the first ceramic layer is less than that near the second conductor pattern of the second ceramic layer.

The term “near” in the expressions “near the first conductor pattern” and “near the second conductor pattern” preferably represents a region to a distance of about 20 μm to 30 μm, for example.

According to another preferred embodiment of the present invention, the first ceramic green layer includes a composition in which Ag does not significantly diffuse during firing. Consequently, it is possible to improve migration resistance on a surface of the first ceramic layer produced by firing the first ceramic green layer.

On the other hand, the second ceramic green layer includes a composition in which Ag diffuses relatively easily during firing, and thus, the softening point of the glass component can be decreased by Ag diffusion. Consequently, it is possible to improve the sinterability of the second ceramic layer produced by firing the second ceramic green layer. Since the first ceramic layer is disposed only in a surface layer portion of the laminated ceramic electronic component, as described above, the improvement in sinterability of the second ceramic layer can improve the reliability and strength of the entire the laminated ceramic electronic component. In addition, moisture does not significantly enter the inner layer portion at which the second ceramic layer is disposed, thereby not significantly influencing the migration resistance.

According to various preferred embodiments of the present invention, the laminated ceramic electronic component is capable of achieving high reliability and strength while maintaining migration resistance. In addition, firing can be performed in an oxidizing atmosphere in the firing step for producing the laminated ceramic electronic component.

According to a preferred embodiment of the present invention, the first ceramic material and the second ceramic material include common constituent elements, and thus, an intermediate product is not formed between the first ceramic green layer and the second ceramic green layer. As a result, the bonding strength between the first ceramic layer and the second ceramic layer after firing is improved.

The above and other features, elements, steps, characteristics and advantages of the present invention will become more apparent from the following detailed description of preferred embodiments of the present invention with reference to the attached drawings.

### BRIEF DESCRIPTION OF THE DRAWINGS

FIG. 1 is a sectional view showing first ceramic green sheets, second ceramic green sheets, and constraining layer green sheets, for explaining a method for manufacturing a laminated ceramic electronic component according to a preferred embodiment of the present invention.

FIG. 2 is a sectional view showing a green composite laminate produced by laminating the first ceramic green sheets, the second ceramic green sheets, and the constraining layer green sheets shown in FIG. 1.

FIG. 3 is a sectional view showing a state after firing of the composite laminate shown in FIG. 2.

FIG. 4 is a sectional view showing a multilayer ceramic substrate after sintering from which the constraining layers shown in FIG. 3 are removed.

FIG. 5 is a sectional view showing a state in which surface mount-type electronic components are mounted on the multilayer ceramic substrate shown in FIG. 4.

### DETAILED DESCRIPTION OF THE PREFERRED EMBODIMENTS

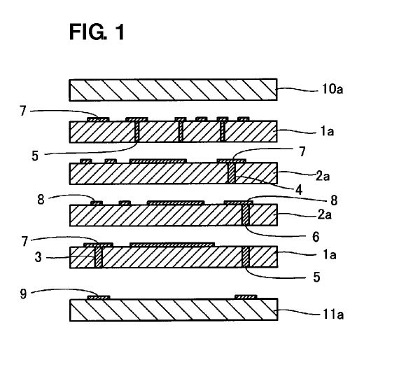

FIGS. 1 to 4 are sectional views for explaining a method for manufacturing a laminated ceramic electronic component according to a preferred embodiment of the present invention. In particular, these figures show a method for manufacturing a multilayer ceramic substrate.

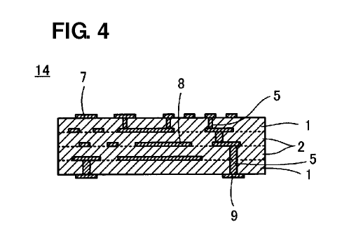

As shown in FIG. 1, first ceramic green sheets 1a defining first ceramic layers 1 (refer to FIG. 4) are prepared, and second ceramic green sheets 2a defining second ceramic layers 2 (refer to FIG. 4) are prepared. The first ceramic green sheets 1a and the second ceramic green sheets 2a include first and second low-temperature sinterable materials including first and second glass components, respectively.

The ceramic green sheets 1a and 2a are each produced by dispersing a ceramic material powder in a vehicle including a binder, a solvent, a plasticizer, and other suitable constituents to prepare a slurry, and forming the resultant slurry into a sheet shape by a casting method, such as a doctor blade method, for example.

The first and the second ceramic materials preferably include common constituent elements. More specifically, both of the first and second ceramic materials are preferably prepared, for example, by melting and vitrifying, at a temperature of about 1200° C. or higher, for example, a mixture including about 0% to about 55% by weight of CaO, about 45% to about 70% by weight of SiO₂, about 0% to about 30% by weight of Al₂O₃, and about 0% to about 10% by weight of impurities, and further including about 5 to about 20 parts by weight of B₂O₃ based on 100 parts by weight of these components, quenching the vitrified product in water, grinding the product into a CaO—SiO₂—Al₂O₃—B₂O₃-based glass powder having an average particle diameter of about 3.0 μm to about 3.5 μm, and mixing the glass powder with an alumina powder.

The glass components included in the first and second ceramic materials may be previously added as glass powders as described above or may be produced from the ceramic materials during the firing step.

During firing, Ag more easily diffuses in the first ceramic green sheets 1a than in the second ceramic green sheet 2a. Examples of a method for this include a method in which the softening point of the second glass component included in the second ceramic green sheets 2a is adjusted to be less than that of the first glass component included in the first ceramic green sheets 1a. In this method, for example, the composition ratios of the glass components are preferably adjusted as follows.

When the glass components include an alkali metal oxide, the content of an alkali metal oxide in the first glass component is adjusted to be less than that in the second glass component. When the glass components include a boron oxide, the content of a boron oxide in the first glass component is adjusted to be less than that in the second glass component.

For example, when the B₂O₃ amount in the CaO—SiO₂—Al₂O₃—B₂O₃-based glass is increased, the softening point of the glass is decreased, and Ag easily diffuses. Therefore, the B₂O₃ amount in glass defining the second glass component is adjusted to be greater than that in glass defining the first glass component.

For example, an acrylic or butyral resin is preferably used as the binder, toluene, xylene, or an aqueous solvent is preferably used as the solvent, and DOP (dioctyl phthalate) or DBP (dibutyl phthalate) is preferably used as the plasticizer.

Next, referring to FIG. 1, interlayer connecting conductor holes 3 and 4 are then formed in the ceramic green sheets 1a and 2a, respectively, by punching, laser processing, or other suitable method. Then, each of the interlayer connecting conductor holes 3 and 4 is filled with conductive paste to form green interlayer connecting conductors 5 and 6.

In addition, conductive paste is printed on each of the ceramic green sheets 1a and 2a to form green in-plane conductors 7 and 8. In the preferred embodiment shown in FIG. 1, an in-plane conductor 9 is also formed on a constraining layer green sheet 11a described below.

As the conductive paste for forming the interlayer connecting conductors 5 and 6 and the in-plane conductors 7 to 9, paste containing Ag as a main component is used.

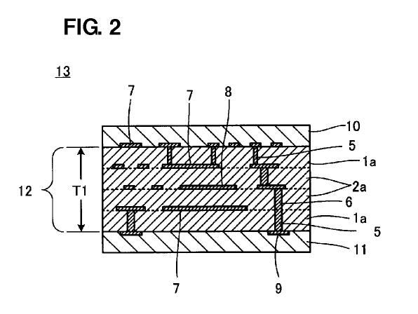

On the other hand, as shown in FIG. 1, constraining layer green sheets 10a and 11a for constraining layers 10 and 11 (refer to FIG. 2) are prepared. The constraining layer green sheets 10a and 11a preferably include a sintering-resistant ceramic material, for example, an alumina powder, which is substantially not sintered at a temperature at which the first and second ceramic materials included in the ceramic green sheets 1a and 2a, respectively, are sintered and a temperature at which the green interlayer connecting conductors 5 and 6 and the green in-plane conductors 7 to 9 are sintered. When the constraining layer green sheets 10a and 11a include an alumina powder, the sintering temperature is about 1500° C. to about 1600° C., and thus, the constraining layer green sheets 10a and 11a are not substantially sintered at the sintering temperatures of the ceramic green sheets 1a and 2a, the interlayer connecting conductors 5 and 6, and the in-plane conductors 7 to 9.

The constraining layer green sheets 10a and 11a are each prepared by dispersing the sintering-resistant ceramic powder in a vehicle containing a binder, a solvent, a plasticizer, and other suitable constituents to prepare a slurry, and forming the resultant slurry into a sheet by a casting method such as a doctor blade method.

Then, a plurality of the first ceramic green sheets 1a and a plurality of the second ceramic green sheets 2a are laminated to form a green ceramic laminate 12 as shown in FIG. 2, conductor patterns, such as the interlayer connecting conductors 5 and 6, and the in-plane conductors 7 to 9 being formed on the ceramic green sheets. In a description below, the first and second ceramic green sheets 1a and 2a after lamination are referred to as “first and second ceramic green layers 1a and 2a”, respectively.

In the green ceramic laminate 12, the first ceramic green layers 1a are laminated with the second ceramic green layers 2a disposed therebetween in the lamination direction, and the first ceramic green layers 1a are arranged along the both respective main surfaces of the green ceramic laminate 12.

The constraining layer green sheets 10a and 11a are laminated with the green ceramic laminate 12 disposed therebetween in the lamination direction. In a description provided below, the reference numerals of the constraining layer green sheets 10a and 11a are changed to “10” and “11”, respectively, and the constraining layer green sheets 10a and 11a after lamination are referred to as “constraining layers 10 and 11”, respectively. In a laminated state, the constraining layers 10 and 11 are in contact with the respective first ceramic green layers 1a.

The constraining layers 10 and 11 may be provided by thick-film printed layers formed by a thick-film printing method, instead of being provided by the green sheets 10a and 11a. Similarly, the first and second ceramic green layers 1a and 2a may be provided by thick-film printed layers formed by a thick-film printing method.

The green ceramic laminate 12 including the constraining layers 10 and 11 produced as described above is pressed by a hydrostatic press or a uniaxial press using a mold, thereby producing a composite laminate 13.

When the green ceramic laminate 12 shown in FIG. 2 assumes a state of a mother stack for producing a plurality of multilayer ceramic substrates, a step of forming grooves to about 20% of the thickness of the green ceramic laminate 12, for example, from at least one of the main surfaces thereof is performed after the composite laminate 13 is formed and before or after the pressing step.

In the green ceramic laminate 12 in a state shown in FIG. 2, the interlayer connecting conductor 5 and the in-plane conductors 7 and 9 provided in contact with each of the first ceramic green layers 1a define first conductor pattern of each of the first ceramic green layers 1a, and the other interlayer connecting conductor 6 and in-plane conductor 8 provided in contact with each of the second ceramic green layers 2a define a second conductor pattern of each of the second ceramic green layers 2a.

Next, the composite laminate 13 is fired in air at a temperature at which the first and second ceramic materials included in the first and second ceramic green layers 1a and 2a, respectively, are sintered, for example, at about 1050° C. or less, and preferably at about 800° C. to about 1000° C.

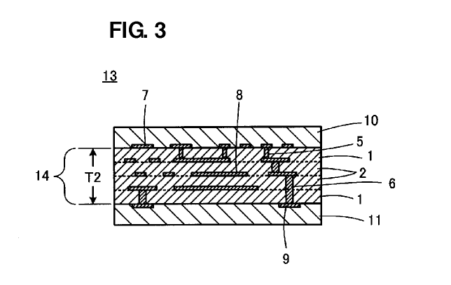

As a result of the firing step, in the composite laminate 13, the green ceramic layer 12 is sintered, while the constraining layers 10 and 11 are substantially not sintered, to produce a sintered ceramic laminate, i.e., a multilayer ceramic substrate 14, between the constraining layers 10 and 11 as shown in FIG. 3.

A comparison between FIGS. 2 and 3 indicates that the multilayer ceramic substrate 14 after sintering is prevented from shrinking in a planar direction by the constraining layers 10 and 11 as compared to the green ceramic laminate 12 before firing.

On the other hand, in the thickness direction, T2<T1 is established, wherein T1 indicates the thickness of the green ceramic laminate 12 shown in FIG. 2, and T2 indicates the thickness of the multilayer ceramic substrate 14 after sintering shown in FIG. 3. Namely, the multilayer ceramic substrate 14 after sintering shrinks a large amount in the thickness direction as compared to the green ceramic laminate 12 before firing.

As described above, the softening point of the first glass component included in the first ceramic green layers 1a is adjusted to be greater than that of the second glass component contained in the second ceramic green layers 2a so that Ag diffuses less in the first ceramic green layers 1a than in the second ceramic green layers 2a during firing.

In general, the sinterability is improved as the softening point of glass decreases. An improvement in the sinterability can decrease the amount of glass in a ceramic material, and thus, the reliability and strength of a multilayer ceramic substrate are desirably improved. In addition, a reduced amount of glass used has the advantage of decreasing the raw material cost.

As a method for decreasing the softening point of glass, as described above, the content of a boron oxide and/or an alkali metal oxide in a glass component is preferably increased. However, this method also has a problem of decreasing the plating resistance of the multilayer ceramic substrate.

When one of the decrease in plating resistance and the Ag diffusion occurs in a surface layer of the multilayer ceramic substrate, a relatively serious problem arises, while in an inner layer portion of the multilayer ceramic substrate, no serious problem arises, but rather, the advantage of improved sinterability is produced. In addition, if the inner layer is compactly fired, the entrance of moisture can be substantially prevented. Therefore, even if relatively large diffusion of Ag occurs, it is not necessary to be concerned about the substantial influence on decreasing the reliability because moisture as a factor of the occurrence of migration is prevented.

From the above consideration, it is discovered that as described above, in the first ceramic green layers 1a, relatively little Ag diffuses during firing, and thus, it is possible to improve the migration resistance on a surface of the multilayer ceramic substrate 14 and to maintain high plating resistance.

On the other hand, the second ceramic green layers 2a have a composition in which Ag diffuse relatively easily during firing, and thus, the softening point of the glass component can be decreased by diffusion of Ag. As a result, the sinterability of the second ceramic layers 2 produced by firing the second ceramic green layers 2a can be improved. Since the first ceramic layers 1 are disposed only in the surface layer portions of the multilayer ceramic substrate 14, as described above, improvements in the sinterability of the second ceramic layers 2 improve the reliability and strength of the entire of the multilayer ceramic substrate 14. In addition, moisture does not significantly enter the inner layer portion at which the second ceramic layers 2 are disposed, thereby not significantly influencing the migration resistance as described above.

Also, as described above, in the green ceramic laminate 12, the first ceramic material included in the first ceramic green sheets 1a and the second ceramic material included in the second ceramic green sheets 2a include common constituent elements. Thus, an intermediate product is not formed between the first ceramic green layers 1a and the second ceramic green layers 2a. As a result, the bonding strength between the first ceramic layers 1 and the second ceramic layers 2 after firing is improved, thereby preventing separation.

Next, the constraining layers 10 and 11 are removed from the composite laminate 13 after firing, for example, using a method, such as wet blasting, sand blasting, brushing, or other suitable method, to produce the multilayer ceramic substrate 14 as shown in FIG. 4.

Then, if required, the surfaces of the multilayer ceramic substrate 14 are washed. As a washing method, a physical treatment, such as ultrasonic washing, spraying of alumina abrasive grains or other suitable method or a chemical treatment such as etching or other suitable method may be used or a combination of these treatments may be used.

In the multilayer ceramic substrate 14 formed as described above, an amount of Ag diffusion near the interlayer connecting conductors 5 and the in-plane conductors 7 and 9 defining the first conductor patterns of the first ceramic layers which define the surface layers is less than that near the interlayer connecting conductors 6 and the in-plane conductors 8 defining the second conductor patterns of the second ceramic layers 2.

Next, the in-plane conductors 7 and 9 exposed on the surfaces of the multilayer ceramic substrate 14 are subjected to plating. The plating is performed to improve the mounting reliability of surface mount-type electronic components described below. For example, plating of Ni/Au, Ni/Pd/Au, Ni/Sn, or other suitable plating materials is performed, and either electroplating or electroless plating may be used as a plating method.

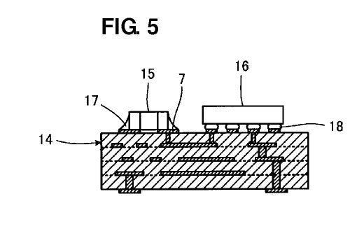

Then, as shown in a sectional view of FIG. 5, surface mount-type electronic components 15 and 16 are mounted on the upper main surface of the multilayer ceramic substrate 14. One of the surface mount-type electronic components 15 is, for example, a chip capacitor and is electrically connected via solder 17 to the in-plane conductors 8 disposed on the outer surface. The other surface mount-type electronic component 16 is, for example, a semiconductor chip and is electrically connected, through bumps 18, to the in-plane conductors 8 disposed on the outer surface. Although not shown in FIG. 5, the surface mount-type electronic components 15 and 16 may be resin-sealed according to demand.

As described above, when the multilayer ceramic substrate 14 is produced in the state of a mother stack, a dividing step is preferably performed after the surface mount-type electronic components 15 and 16 are mounted.

Although the present invention is described above with reference the preferred embodiments shown in the drawings, other various preferred embodiments can be provided within the scope of the present invention.

In the multilayer ceramic substrate 14, the number of the first ceramic layers 1 and the number of the second ceramic layers 2, particularly the number of the second ceramic layers 2, can be arbitrarily changed according to necessary design parameters.

The above-described preferred embodiments preferably uses a firing method based on a so-called non-shrink process using the constraining layers 10 and 11. However, the multilayer ceramic substrate may be produced by using a firing method not using constraining layers.

Also, preferred embodiments of the present invention can be applied not only to the multilayer ceramic substrate but also to laminated ceramic electronic components having other functions.

Next, an experimental example performed to confirm the advantages of preferred embodiments of the present invention is described.

First ceramic green sheets and second ceramic green sheets each including an alumina powder and a borosilicate glass powder at a weight ratio of about 60:40 were prepared. The composition ratios of borosilicate glass included in the first ceramic green sheets defining the surface layers and borosilicate glass included in the second ceramic green sheets defining the inner layers were as shown in Table 1 below.

TABLE 1

| | Glass composition for first | Glass composition for second |
|---|---|---|
| | ceramic green sheet | ceramic green sheet |
| | (% by weight) | (% by weight) |
| SiO₂ | 46 | 59 |
| B₂O₃ | 4 | 10 |
| CaO | 43 | 25 |
| Al₂O₃ | 7 | 6 |

As shown in Table 1, the B₂O₃ amount of borosilicate glass included in the second ceramic green sheets was greater than that included in the first ceramic green sheets, and thus, the glass softening point of the second ceramic green sheets was less than that of the first ceramic green sheets.

In addition, an in-plane conductor and an interlayer connecting conductor were formed on each of the first and second ceramic green sheets using conductive paste including Ag as a main component. In addition, a comb-shaped electrode having line/space of about 100 μm/100 μm was formed on, particularly, an outward-facing main surface of each of the first ceramic green sheets.

On the other hand, constraining layer green sheets each including an alumina powder with an average particle diameter D50 of about 1.0 μm and having a thickness of about 300 μm were prepared.

Next, desired numbers of the first ceramic green sheets and the second ceramic green sheets were laminated so that the total thickness of first ceramic layers on each surface side was about 0.015 mm, and the total thickness of the second ceramic layers disposed between the first ceramic layers in the lamination direction was about 0.300 mm to prepare a green ceramic laminate. Further, the constraining layer green sheets were laminated so as to hold the green ceramic laminate in the lamination direction and pressure-bonded together to form a green composite laminate.

Next, the green composite laminate was fired at a temperature of about 900° C., and then the constraining layers were removed by wet blasting to produce a multilayer ceramic substrate of an example within the scope of preferred embodiments of the present invention.

On the other hand, as comparative multilayer ceramic substrates outside of the scope of the present invention, a multilayer ceramic substrate was formed by laminating only the first ceramic green sheets (Comparative Example 1) and a multilayer ceramic substrate was formed by laminating only the second ceramic green sheets (Comparative Example 2).

Each of the multilayer ceramic substrates of the Example and Comparative Examples 1 and 2 formed as described above was evaluated with respect to a density and subjected to a reliability test by applying a voltage of about DC 20 V to the comb-like electrodes in an environment at a temperature of about 85° C. and a humidity of about 85%.

As a result, in the Example, a compact sintered body was produced, and no failure occurred in the reliability test for about 1000 hours. In contrast, in Comparative Example 1, a compact sintered body was not produced. In Comparative Example 2, a compact sintered body was produced, but in the reliability test, dielectric breakdown occurred due to Ag migration after the passage of about 167 hours.

As a result of evaluation of the amount of Ag diffusion in Example by WDX mapping analysis, it was confirmed that the amount of Ag diffusion in the second ceramic layers as the inner layers is larger than that in the first ceramic layers as the surface layers.

While preferred embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. A method for manufacturing a laminated ceramic electronic component comprising the steps of:
forming a green ceramic laminate; and
firing the green ceramic laminate; wherein
the green ceramic laminate includes:
a first ceramic green layer which includes a first conductor pattern including Ag as a main component and which includes a first ceramic material including a first glass component; and
a second ceramic green layer which includes a second conductor pattern including Ag as a main component, which includes a second ceramic material including a second glass component, and which includes a composition in which Ag diffuses more easily than in the first ceramic green layer during firing, the first ceramic green layer being disposed along each of both main surfaces while exposing at least a portion of the first conductor pattern on a surface.

2. The method for manufacturing a laminated ceramic electronic component according to claim 1, wherein the first glass component has a higher softening point than the second glass component.

3. The method for manufacturing a laminated ceramic electronic component according to claim 2, wherein the first glass component includes a lower content of alkali metal oxide than that of the second glass component.

4. The method for manufacturing a laminated ceramic electronic component according to claim 2, wherein the first glass component includes a lower content of boron oxide than that of the second glass component.

5. The method for manufacturing a laminated ceramic electronic component according to claim 1, wherein the first glass component and the second glass component include common constituent elements.

6. A laminated ceramic electronic component comprising:
a first ceramic layer which includes a first conductor pattern including Ag as a main component and which includes a first glass component; and
a second ceramic layer which includes a second conductor pattern including Ag as a main component and which includes a second glass component; wherein
the first ceramic layer is arranged to define a surface layer portion with at least a portion of the first conductor pattern is exposed on a surface;
the second ceramic layer is arranged to define an inner layer portion; and
an amount of Ag diffusion near the first conductor pattern of the first ceramic layer is less than that near the second conductor pattern of the second ceramic layer.
